(19) United States
(12) Patent Application Publication
(10) Pub. No.: US 2025/0142844 A1
(43) Pub. Date: May 1, 2025

(54) SEMICONDUCTOR STRUCTURE AND METHOD FOR FABRICATING SAME

(71) Applicant: Hangzhou HFC Semiconductor Co., Hangzhou (CN)

(72) Inventors: Mingyu HU, Dalian (CN); Liang LI, SINGAPORE (SG); Xu ZHANG, Zhejiang (CN); Haijiang YUAN, Shanghai (CN)

(21) Appl. No.: 18/530,719

(22) Filed: Dec. 6, 2023

(30) Foreign Application Priority Data
Oct. 27, 2023 (CN) 202311414513.2

(51) Int. Cl. H01L 29/94; H01L 29/66

(52) U.S. Cl. CPC H10D 1/665; H10D 1/047

(57) ABSTRACT

A semiconductor structure and method for fabricating it are disclosed. The method includes: providing a semiconductor substrate including a BOX layer, at least one fin structure, a DTC, an isolation layer and an HARP layer, the semiconductor substrate divided into a fin structure region and a DT region; thinning the HARP layer, with the remaining portion of the HARP layer being retained above the BOX layer; removing the isolation layer and the HARP layer from the fin structure region; forming a first oxide layer over the semiconductor substrate; and forming layer-stacked structures and sidewall spacers. According to the present invention, the thinned HARP layer being retained above the BOX layer and is subsequently removed only from the fin structure region.

### CROSS-REFERENCE TO RELATED APPLICATION

This application claims the priority of Chinese patent application number 202311414513.2, filed on Oct. 27, 2023, and entitled “SEMICONDUCTOR STRUCTURE AND METHOD FOR FABRICATING SAME”, the entire contents of which are incorporated herein by reference.

### TECHNICAL FIELD

The present invention relates to the field of semiconductor technology and, in particular, to a semiconductor structure and a method for fabricating it.

### BACKGROUND

Deep trench capacitors (DTCs) are vertical semiconductor devices, which are used in various integrated circuits to provide capacitance. Manufacturers of silicon-based integrated circuits, such as those comprising field-effect transistors (FETs) or metal-insulator-semiconductor FETs (MOSFETs), have been pursuing higher speed, higher integration density and more powerful functions.

FIGS. 1A to 2B show a semiconductor structure combining a DTC with a transistor (e.g., FinFET). FIG. 1A is a top view of a fin structure and the DTC in the semiconductor structure. FIG. 1B is a schematic cross-sectional view of an intermediate structure of the semiconductor structure prior to the formation of layer-stacked structures taken along line CC′ (extending in the same direction as the fin structure). FIG. 1C is a schematic cross-sectional view of the intermediate structure of the semiconductor structure prior to the formation of the layer-stacked structures taken along line DD′ (extending perpendicular to the direction of the fin structure). FIG. 2A is a schematic cross-sectional view of an intermediate structure of the semiconductor structure after the layer-stacked structures are formed taken along line CC′. FIG. 2B is a schematic cross-sectional view of the intermediate structure of the semiconductor structure after the layer-stacked structures are formed taken along line DD′. Lines CC′ and DD′ are shown in FIG. 1A. Generally, the semiconductor structure includes: a semiconductor substrate including a buried oxide (BOX) layer 011, the fin structure 016 located on a portion of the BOX layer 011, the DTC 012 extending through the BOX layer 011, a silicon oxide layer 013 and a silicon nitride layer 014 located above the DTC 012, and a high aspect ratio process (HARP) layer 015 located on a portion of the silicon nitride layer 014; a first oxide layer 017 located above the semiconductor substrate; the layer-stacked structure located on the first oxide layer 017; and sidewall spacers 021 located on sidewalls of the layer-stacked structures. The layer-stacked structures may each include, sequentially stacked one above another, a polysilicon layer 018, a silicon nitride hard mark 019 and a silicon oxide hard mark 020. The silicon nitride hard mark 019 and the overlying silicon oxide hard mark 020 are intended to provide protection during an etching process involved in the formation of the layer-stacked structures. Existing methods for fabricating such semiconductor structures are generally associated with the problems as follows: 1) during the formation of the HARP layer 015 in the deep trench (DT) region, residues tend to remain on the fin structure 016 and require removal with over etch using buffered hydrofluoric (BHF) acid, which, however, may dish the HARP layer 015 and thus perhaps create a high epitaxial layer (EPI) short risk; 2) since the BHF-based over etch for removing the residues on the fin structure 016 tends to easily affect the subsequent processes (e.g., due to dishing of the HARP layer 015), the BHF-based process is difficult to control, and patterning over the DT region is prone to inefficiency; 3) a cyclic process involving complicated and time-consuming steps; and 4) repeated film deposition and etching necessitate complex online monitoring, raising the fabrication cost.

Some methods have been proposed involving a cyclic process with fewer steps, but they could not solve the short circuit and other problems. For example, U.S. Pat. No. 8,673,729 B1 discloses a method involving a cyclic process with fewer steps. However, it is still associated with a high EPI short risk, and involves a reactive ion etching (RIE) process on an isolation layer, which, however, tends to cause damage to the fin structure. U.S. Pat. No. 8,946,802 B2 discloses another method involving a cyclic process with fewer steps, which, however, is associated with a high EPI short risk.

### SUMMARY OF THE INVENTION

It is an object of the present invention to provide a semiconductor structure and a method for fabricating the structure, with a lower EPI short risk.

In order to achieve the above and other objects, the present invention provides a method for fabricating a semiconductor structure, comprising:
providing a semiconductor substrate, comprising: a BOX layer; a fin structure on a portion of the BOX layer; a DTC extending through the BOX layer; an isolation layer located on the fin structure, the DTC and the BOX layer; and an HARP layer located on the isolation layer, wherein the semiconductor substrate is divided into a fin structure region and a DT region adjacent to and connected with the fin structure region, wherein the fin structure region comprises the fin structure, the DT region comprises the DTC;
thinning the HARP layer, with a remaining portion of the HARP layer being retained above the BOX layer;
removing the isolation layer and the HARP layer from the fin structure region;
forming a first oxide layer over the semiconductor substrate;
forming layer-stacked structures on the first oxide layer; and
forming a sidewall spacer on each sidewall of the layer-stacked structure.

In order to realize the above and other objects, the present invention further provides a semiconductor structure, comprising:
a semiconductor substrate, comprising: a BOX layer; a fin structure located on a portion of the BOX layer; a DTC extending through the BOX layer; an isolation layer covering each of the DTC and the BOX layer in a DT region; and an HARP layer located on the isolation layer, wherein the HARP layer is located above; the BOX layer in the DT region and a portion of the DTC, the semiconductor substrate divided into the DT region and a fin structure region adjacent to and connected with the DT region, the fin structure region comprising the fin structure, the DT region comprising the DTC;
a first oxide layer located over the semiconductor substrate;
layer-stacked structures located on the first oxide layer; and
a plurality of sidewall spacers located on sidewalls of the layer-stacked structures.

Compared with the prior art, the present invention offers the benefits as follows:

In the method, since the HARP layer still remains above the BOX layer in the DT region after the layer-stacked structures are formed, the problem of dishing can be prevented, resulting in a reduced short risk.

Moreover, the HARP layer is first thinned by successive CMP and BHF processes and then completely removed from the fin structure region by using a mask layer. This can ensure absence of residues on the fin structure while preventing dishing of the HARP layer in the DT region, and the two BHF processes are easy to control.

Further, the method involves only one photolithography process and dispenses with the need for nitride removal and deposition, entailing a cyclic process, which is simpler, involves fewer steps, is more time-saving and can result in cost savings.

### BRIEF DESCRIPTION OF THE DRAWINGS

FIG. 1A is a top view of a fin structure and a DTC according to prior art.

FIG. 1B is a schematic cross-sectional view of an intermediate structure prior to the formation of layer-stacked structures, taken along line CC′.

FIG. 1C is a schematic cross-sectional view of the intermediate structure prior to the formation of the layer-stacked structures, taken along line DD′.

FIG. 2A is a schematic cross-sectional view of an intermediate structure after the layer-stacked structures are formed, taken along line CC′.

FIG. 2B is a schematic cross-sectional view of the intermediate structure after the layer-stacked structures are formed, taken along line DD′.

FIG. 3 is a top view of a fin structure and a DTC according to an embodiment of the present invention.

FIG. 4A is a schematic cross-sectional view of an intermediate structure resulting from step S1 in a method for fabricating a semiconductor structure according to an embodiment of the present invention, taken along line AA′.

FIG. 4B is a schematic cross-sectional view of the intermediate structure resulting from step S1 in the method according to an embodiment of the present invention, taken along line BB′.

FIG. 5A is a schematic cross-sectional view of an intermediate structure resulting from step S2 in the method according to an embodiment of the present invention, taken along line AA′.

FIG. 5B is a schematic cross-sectional view of the intermediate structure resulting from step S2 in the method according to an embodiment of the present invention, taken along line BB′.

FIG. 6A is a schematic cross-sectional view of an intermediate structure resulting from step S31 in the method according to an embodiment of the present invention, taken along line AA′.

FIG. 6B is a schematic cross-sectional view of the intermediate structure resulting from step S31 in the method according to an embodiment of the present invention, taken along line BB′.

FIG. 7A is a schematic cross-sectional view of an intermediate structure resulting from step S322 in the method according to an embodiment of the present invention, taken along line AA′.

FIG. 7B is a schematic cross-sectional view of the intermediate structure resulting from step S322 in the method according to an embodiment of the present invention, taken along line BB′.

FIG. 8A is a schematic cross-sectional view of an intermediate structure resulting from step S323 in the method according to an embodiment of the present invention, taken along line AA′.

FIG. 8B is a schematic cross-sectional view of the intermediate structure resulting from step S323 in the method according to an embodiment of the present invention, taken along line BB′.

FIG. 9A is a schematic cross-sectional view of an intermediate structure resulting from step S33 in the method according to an embodiment of the present invention, taken along line AA′.

FIG. 9B is a schematic cross-sectional view of the intermediate structure resulting from step S33 in the method according to an embodiment of the present invention, taken along line BB′.

FIG. 10A is a schematic cross-sectional view of an intermediate structure resulting from step S33 in the method according to an embodiment of the present invention, taken along line AA′.

FIG. 10B is a schematic cross-sectional view of the intermediate structure resulting from step S33 in the method according to an embodiment of the present invention, taken along line BB′.

FIG. 11A is a schematic cross-sectional view of an intermediate structure resulting from step S34 in the method according to an embodiment of the present invention, taken along line AA′.

FIG. 11B is a schematic cross-sectional view of the intermediate structure resulting from step S34 in the method according to an embodiment of the present invention, taken along line BB′.

FIG. 12A is a schematic cross-sectional view of an intermediate structure resulting from step S35 in the method according to an embodiment of the present invention, taken along line AA′.

FIG. 12B is a schematic cross-sectional view of the intermediate structure resulting from step S35 in the method according to an embodiment of the present invention, taken along line BB′.

FIG. 13A is a schematic cross-sectional view of an intermediate structure resulting from step S4 in the method according to an embodiment of the present invention, taken along line AA′.

FIG. 13B is a schematic cross-sectional view of the intermediate structure resulting from step S4 in the method according to an embodiment of the present invention, taken along line BB′.

FIG. 14A is a schematic cross-sectional view of an intermediate structure resulting from step S5 in the method according to an embodiment of the present invention, taken along line AA′.

FIG. 14B is a schematic cross-sectional view of the intermediate structure resulting from step S5 in the method according to an embodiment of the present invention, taken along line BB′.

### DETAILED DESCRIPTION

The semiconductor structure and method proposed in the present invention will be described in greater detail below with reference to the accompanying drawings and specific embodiments. From the following description, advantages and features of this invention will become more apparent. Note that the figures are provided in a very simplified form not necessarily drawn to exact scale and only for the sake of easier and clearer description of the embodiments disclosed herein.

The present invention provides a method for fabricating a semiconductor structure, comprising:
S1: providing a semiconductor substrate, comprising: a buried oxide (BOX) layer; a fin structure on a portion of the BOX layer; a deep trench capacitor (DTC) extending through the BOX layer; an isolation layer located on the fin structure, the DTC and the BOX layer; and a high aspect ratio process (HARP) layer on the isolation layer, the semiconductor substrate divided into a fin structure region comprising the fin structure and a deep trench (DT) region adjacent to and connected with the fin structure region and comprising the DTC;
S2: thinning the HARP layer, with a remaining portion of the HARP layer being retained above the BOX layer;
S3: removing the isolation layer and the HARP layer from the fin structure region;
S4: forming a first oxide layer over the semiconductor substrate; and
S5: forming layer-stacked structures on the first oxide layer and sidewall spacers on sidewalls of the layer-stacked structures.

FIG. 3 is a top view of a fin structure and a DTC according to an embodiment of the present invention. All the schematic cross-sectional views illustrating this embodiment are taken along line AA′ (extending in the same direction as the fin structure) and BB′ (extending perpendicular to the direction of extension of the fin structure) that can be found in FIG. 3.

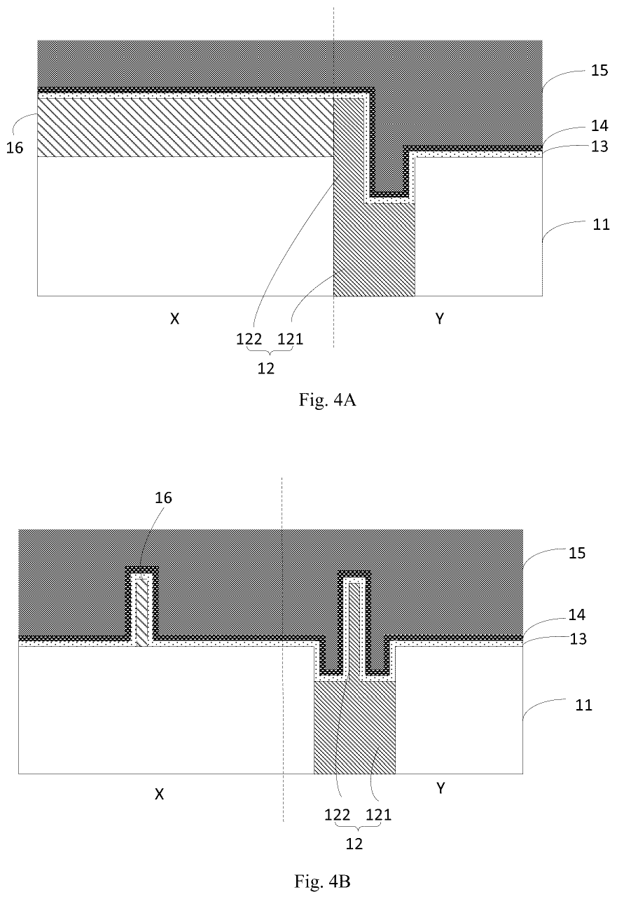

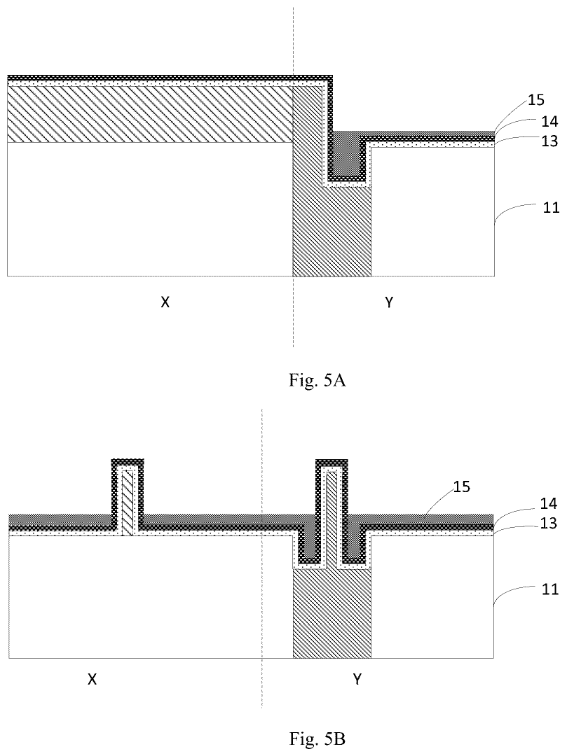

Referring to FIGS. 4A and 4B, in step S1, a semiconductor substrate is provided. In this embodiment, the semiconductor substrate may include a buried oxide (BOX) layer 11, a fin structure 16, a deep trench capacitor (DTC) 12, an isolation layer and a high aspect ratio process (HARP) layer 15.

The semiconductor substrate may further include a doped substrate layer (not shown), on which the BOX layer 11 is located. Without limitation, the semiconductor substrate is preferred to be a silicon-on-insulator (SOI) substrate, and the doped substrate layer is preferred to be a heavily-doped N-type silicon layer. The semiconductor substrate is divided into a fin structure region X and a deep trench (DT) region Y adjacent to and connected with the fin structure region X. The fin structure 16 is located in the fin structure region X, and the DTC 12 is located in the DT region Y.

Preferably, but without limitation, the BOX layer 11 is made of silicon oxide. The fin structure 16 is located on a portion of the BOX layer 11. Preferably, but without limitation, the fin structure 16 is made of silicon. The DTC 12 extends through the BOX layer 11 and includes a trench portion 121 and a fin portion 122 on the trench portion 121. The top of the trench portion 121 is lower than a top of the BOX layer 11, but the top of the fin portion 122 is higher than a top of the BOX layer 11. Moreover, the fin portion 122 is as high as the fin structure 16. Without limitation, the trench portion 121 may include a doped polysilicon layer. For example, it may further include a node dielectric layer and a barrier layer, which are sequentially stacked over bottom and side surfaces of the doped polysilicon layer. The fin portion 122 may include a doped polysilicon layer. In this embodiment, the DTC 12 extends through the BOX layer 11 in the semiconductor substrate into the doped substrate layer.

The isolation layer extends on the fin structure 16, the DTC 12 and the BOX layer 11. In this embodiment, the isolation layer may include, sequentially stacked one above the other, oxide pad layer 13 and a nitride pad layer 14. That is, the oxide pad layer 13 and the nitride pad layer 14 are sequentially stacked on the fin structure 16, the DTC 12 and the BOX layer 11. Preferably, but without limitation, the oxide pad layer 13 is silicon oxide. Preferably, but without limitation, the nitride pad layer 14 is silicon nitride.

The HARP layer 15 is located on the nitride pad layer 14. Preferably, but without limitation, the HARP layer 15 is silicon oxide. The HARP layer 15 may be formed using either an HARP process, or an enhanced HARP (eHARP) process. A thickness of the HARP layer 15 above the fin structure 16 may be adjusted as required. For example, it may range from 100 nm to 200 nm.

Referring to FIGS. 5A and 5B, in step S2, the HARP layer 15 is thinned, and its remaining portion is still located above the BOX layer 11. In this embodiment, the thinning of the HARP layer 15 may include:
S21: performing a chemical mechanical polishing (CMP) process on the HARP layer 15, which stops at the isolation layer; and
S22: performing a wet etching process on the HARP layer 15, which stops upon the remaining portion of the HARP layer reaching a predetermined thickness. That is, the HARP layer 15 is thinned by successively performing the CMP and wet etching processes thereon. During the further thinning by the wet etching process, the HARP layer 15 above the fin structure 16 may be removed, with the remaining portion of the HARP layer 15 resulting from the wet etching process being retained above the BOX layer 11. The thickness of the remaining portion of the HARP layer 15 may be adjusted as required. In this embodiment, the predetermined thickness refers to the thickness of the remaining portion of the HARP layer 15 above the BOX layer 11. The thickness of the remaining portion of the HARP layer 15 above the BOX layer 11 is preferred to range from 5 nm to 10 nm. According to this embodiment, if the thickness of the remaining portion of the HARP layer 15 above the BOX layer 11 is greater than 10 nm, resistance performance will be affected. According to this embodiment, the remaining portion of the of the HARP layer 15 located above both the BOX layer 11 and the trench portion 121 and is uniformly high at the top. According to this embodiment, the remaining portion of the HARP layer 15 resulting from the wet etching process fills up the recess between the trench portion 121 and the BOX layer 11 and is not dished at all. This can avoid bridging to an EPI layer grown around any neighboring fin structure in a subsequent EPI process, leading to a reduced EPI short risk.

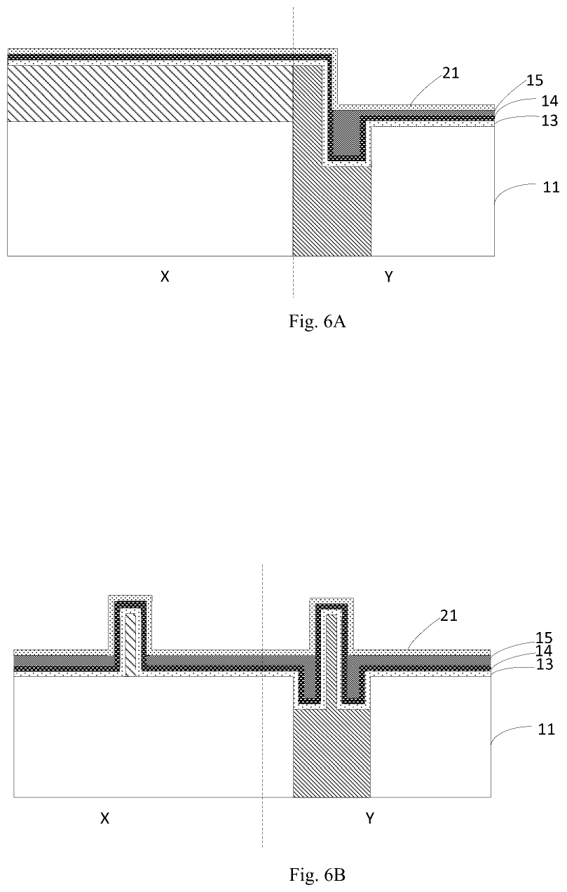

Referring to FIGS. 6A to 12B, in step S3, removing the isolation layer and the HARP layer 15 from the fin structure region X, thereby patterning the isolation layer and the HARP layer. This may include the steps as follows.

Referring to FIGS. 6A and 6B, in step S31, a second oxide layer 21 is formed over the semiconductor substrate after the HARP layer 15 is thinned. The second oxide layer 21 covers both the nitride pad layer 14 and the HARP layer 15. Preferably, but without limitation, the second oxide layer 21 is silicon oxide. The second oxide layer 21 is preferred to have a thickness in the range of 20 Å to 30 Å. Preferably, but without limitation, the formation of the second oxide layer 21 is accomplished using a plasma-enhanced atomic layer deposition (PEALD) process.

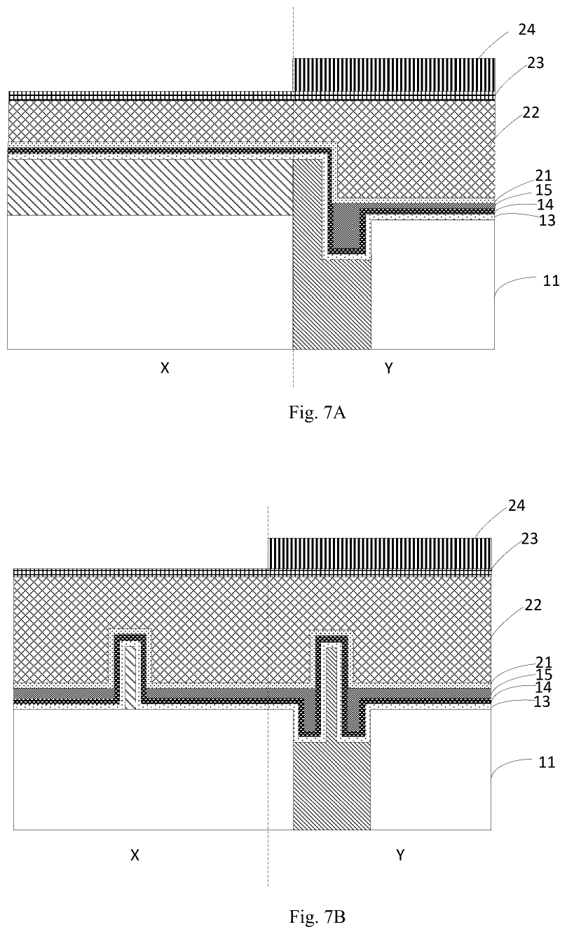

Referring to FIGS. 7A to 9B, in step S32, a mask layer is formed on the second oxide layer 21 in the DT region Y. In this embodiment, the mask layer includes, a patterned organic planarization layer (OPL) 221 and a patterned anti-reflective coating (ARC) 231, which are sequentially stacked one above the other. The formation of the mask layer may include the steps as follows.

Referring to FIGS. 7A and 7B, in step S321, the OPL 22, ARC 23 and a photoresist layer are successively deposited over the second oxide layer 21. In this embodiment, the OPL 22 may be a self-planarizing low-viscosity organic polymer material, and the ARC 23 may be a silicon-containing ARC (SiARC).

With continued reference to FIGS. 7A and 7B, in step S322, a photolithography process is performed on the photoresist layer to form a patterned photoresist layer 24. The patterned photoresist layer 24 covers a portion of the ARC 23 in the DT region Y. As a result, a window is opened in a portion of the photoresist layer 24 over the fin structure region X.

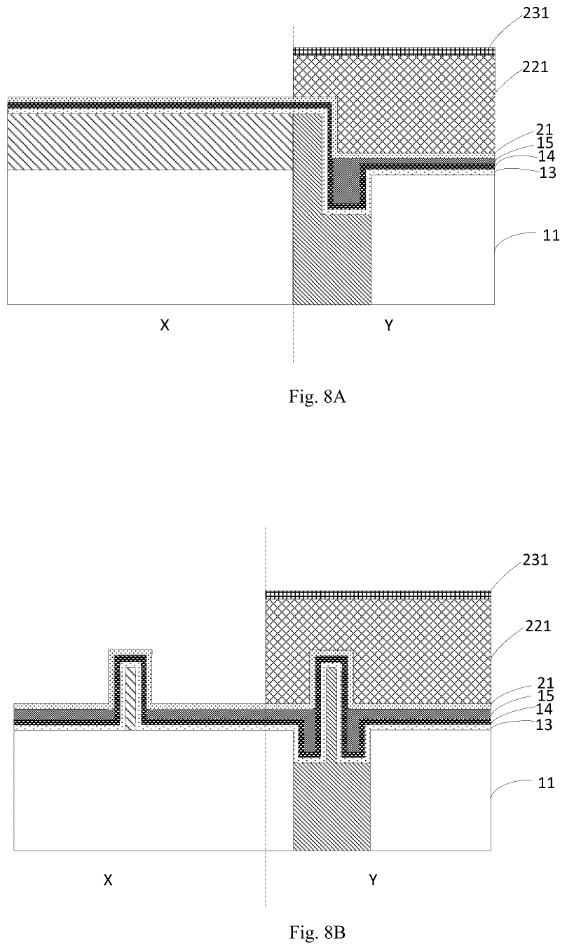

Referring to FIGS. 8A and 8B, in step S323, the patterned OPL 221 and ARC 231 are formed by successively etching through the OPL 22 and the ARC 23, with the patterned photoresist layer 24 serving as a mask, exposing a portion of the second oxide layer 21 above the fin structure region X. In this embodiment, preferably, but without limitation, a dry etching process is employed to etch through the OPL 22 and the ARC 23.

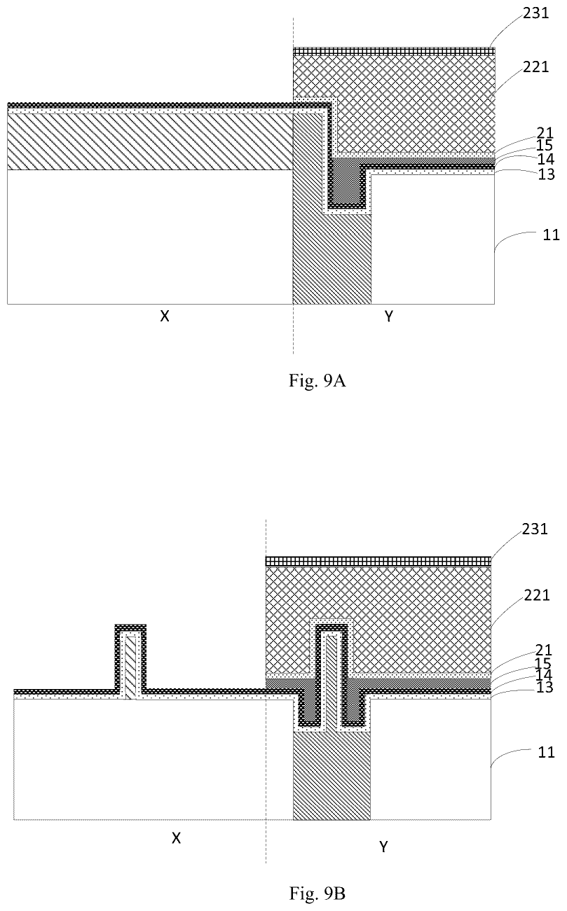

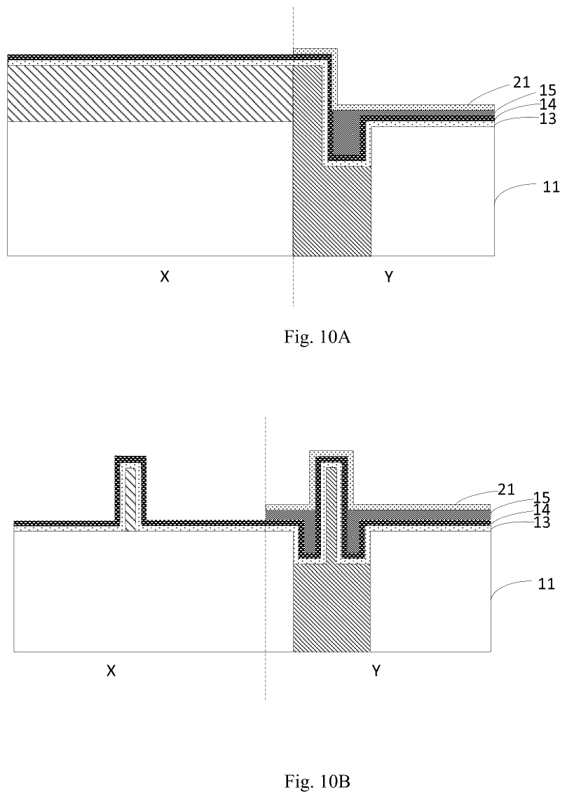

Referring to FIGS. 9A and 9B, in step S33, with the mask layer as a mask, the second oxide layer 21 and the HARP layer 15 are successively etched through, exposing a portion of the nitride pad layer 14. As a result, the second oxide layer and the HARP layer are patterned. That is, a portion of the second oxide layer 21 and a portion of the HARP layer 15 above the fin structure region X are removed, while a remaining portion of the second oxide layer 21 and a remaining portion of the HARP layer 15 above the DT region Y are retained. According to this embodiment, the patterned HARP layer above the BOX layer 11 may have a thickness and width adjustable based on requirement of a subsequent etching process for forming sidewall spacers.

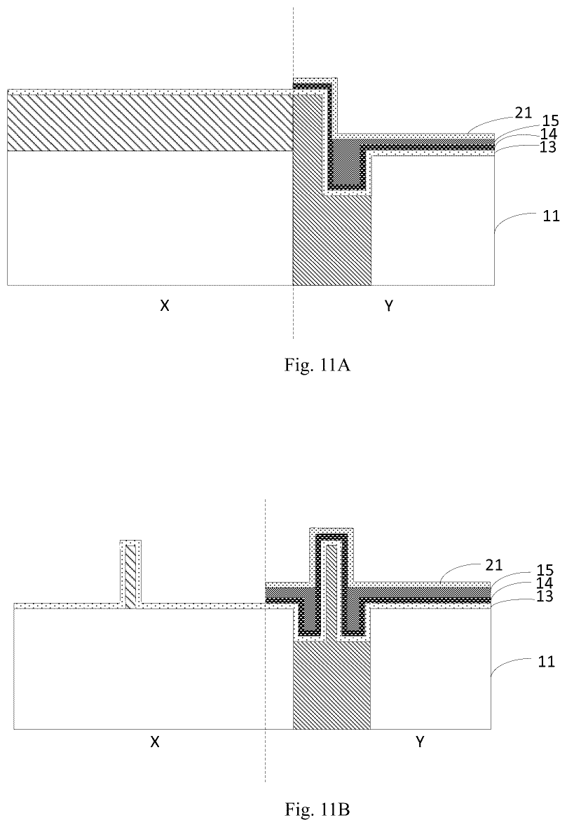

Referring to FIGS. 10A and 10B, after step S33 and before step S34, the method may further include removing the patterned OPL 221 and ARC 231, exposing the remaining portion of the second oxide layer 21. According to this embodiment, the removal of the patterned OPL 221 and ARC 231 may be accomplished using a technique known in the art.

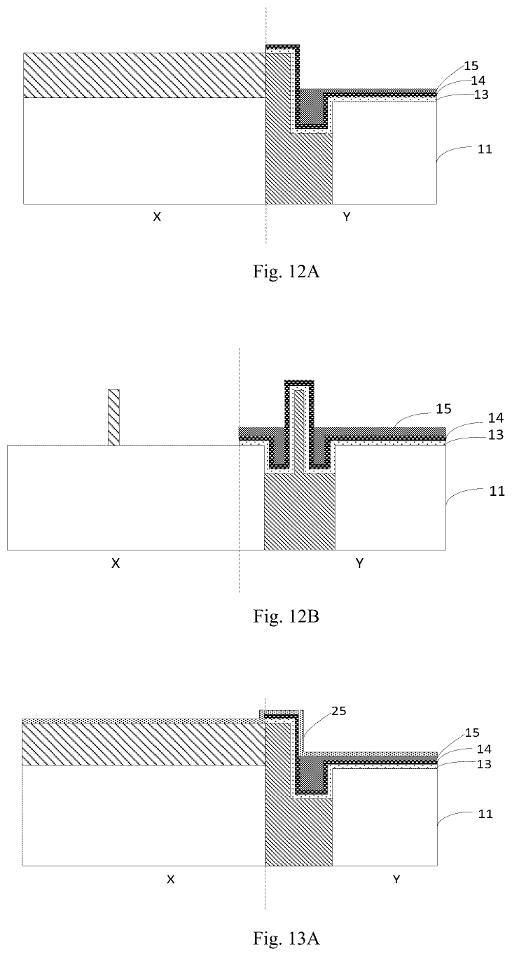

Referring to FIGS. 11A and 11B, in step S34, the nitride pad layer 14 is etched with the remaining portion of the second oxide layer 21 as a mask, exposing a portion of the oxide pad layer 13. In this embodiment, preferably, but without limitation, the nitride pad layer 14 is etched using a wet etching process preferably using a phosphoric acid solution.

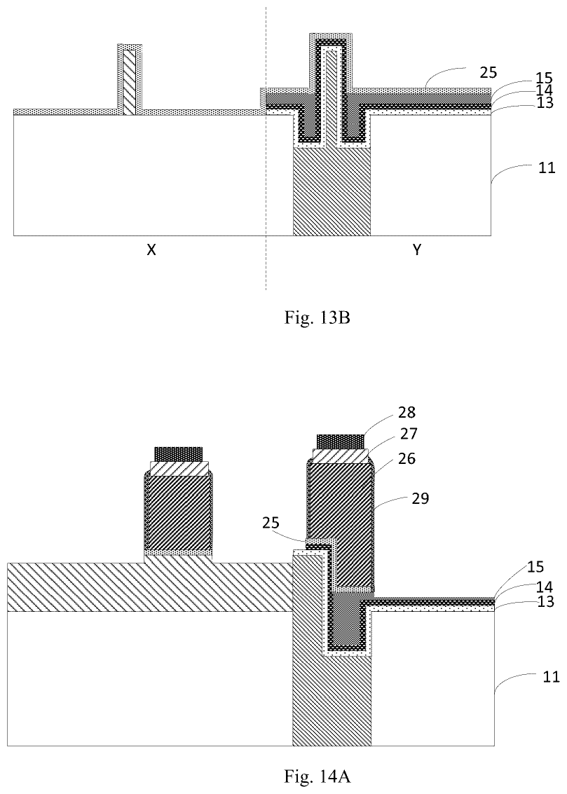

Referring to FIGS. 12A and 12B, in step S35, each of the exposed oxide pad layer 13 and the remaining portion of the second oxide layer 21 is removed using a wet etching process, exposing the fin structure 16, the BOX layer 11, the nitride pad layer 14 and the HARP layer 15.

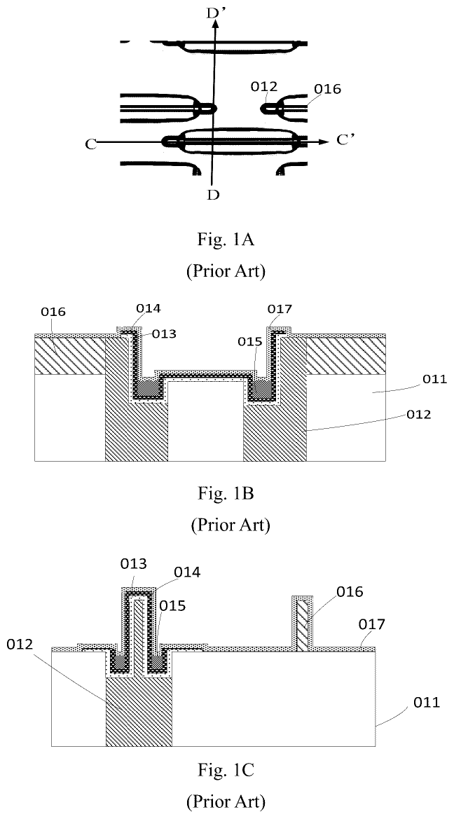

Referring to FIGS. 13A and 13B, in step S4, a first oxide layer 25 is formed over the semiconductor substrate. In this embodiment, the first oxide layer may serve as a gate oxide layer. The first oxide layer 25 may be formed using atomic layer deposition (ALP) or chemical vapor deposition (CVD), such as low-pressure CVD (LPCVD), rapid thermal CVD (RTCVD), plasma-enhanced CVD (PECVD) or high-density plasma CVD (HDPCVD). Preferably, but without limitation, the first oxide layer 25 is silicon oxide. According to this embodiment, the first oxide layer 25/HARP layer 15, the nitride pad layer 14 and the oxide pad layer 13 make up an oxide-nitride-oxide (ONO) layer. As an insulating layer for the DTC 12, this ONO layer provides good isolation, which can prevent short between the DTC 12 and any layer-stacked structure and leakage of polysilicon in the DTC 12. Different from the conventional structure shown in FIGS. 1B and 1C, after formation of the first oxide layer 25 in this embodiment, the HARP layer 15 is higher than the BOX layer 11 and is not dished at all. Moreover, the height of the HARP layer 15 is adjustable. Therefore, according to this embodiment, before an EPI process is carried out, the fin portion is not excessively exposed, leading to a reduced EPI short risk. Further, conventionally, the formation of the ONO layer would involve a first photolithography process, removal and re-deposition of a nitride pad layer, a second photolithography process and an oxide deposition process. In contrast, this can be achieved simply by the second photolithography and oxide deposition processes according to this embodiment, saving the first photolithography process and the removal and re-deposition of a nitride pad layer. More precisely, about eight steps can be saved. Therefore, this embodiment entails a simpler process involving fewer steps and can result in cost savings.

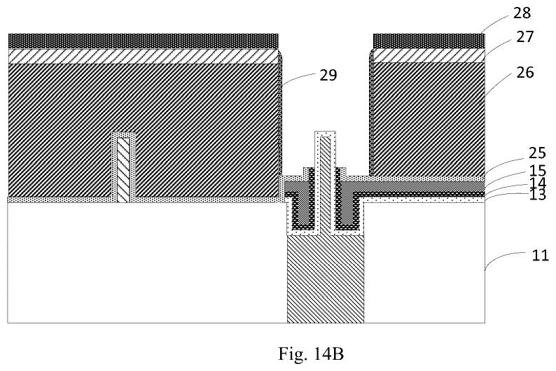

Referring to FIGS. 14A and 14B, in step S5, layer-stacked structures are formed above the first oxide layer 25. At least one of the layer-stacked structures intersects the fin structure 16, and at least one of the layer-stacked structures is located on the first oxide layer 25 above the DTC 12. In this embodiment, the first oxide layer 25/HARP layer 15, the nitride pad layer 14 and the oxide pad layer 13 over the DTC 12 make up an insulating layer for the layer-stacked structures, which insulates the layer-stacked structures from the DTC 12 and prevent short between the DTC 12 and the layer-stacked structures. The layer-stacked structures may each include, a polysilicon layer 26, a silicon nitride hard mark 27 and a silicon oxide hard mark 28, which are sequentially stacked one above another. The polysilicon layer 26 may be formed by depositing and then etching polysilicon. Hard marks (e.g., the silicon nitride hard mark 27 and the overlying silicon oxide hard mark 28) can provide protection during the etching of the polysilicon.

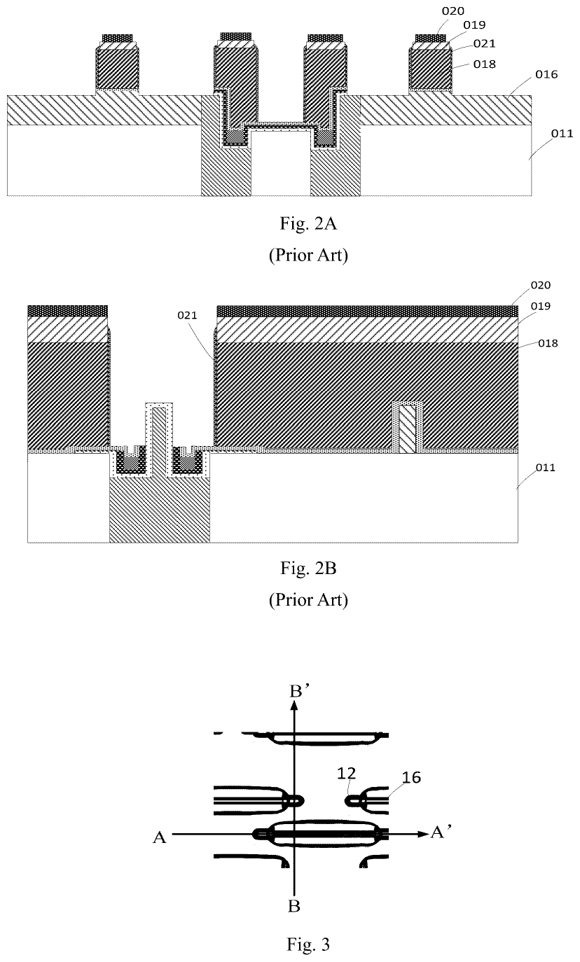

With continued reference to FIGS. 14A and 14B, after the layer-stacked structures are formed on the first oxide layer 25, sidewall spacers 29 are formed on sidewalls of the layer-stacked structures. For example, the formation of the sidewall spacers 29 may include: depositing silicon carbonitride (SiCN) after the layer-stacked structures are formed; and then etching the SiCN, the first oxide layer 25 and a portion thickness of the HARP layer 15 using an anisotropic etching process. As a result, the HARP layer 15 is exposed, and the remaining portion of SiCN covers opposite sides of the layer-stacked structures and forms the sidewall spacers 29. Preferably, but without limitation, the etching process for forming the sidewall spacers 29 is a reactive ion etching (RIE) process. During the formation of the sidewall spacers 29, the insulating layer of the layer-stacked structures can provide protection to the DTC 12. Compared with the conventional structure shown in FIGS. 2A and 2B, according to this embodiment, the HARP layer 15 is not dished at all after the sidewall spacers are formed. This can avoid bridging to an EPI layer grown around any neighboring fin structure. Further, since the HARP layer 15 covers the isolation layer overlying the BOX layer 11 and a thickness and width thereof may be adjustable, it has sufficiently large edge portions that can accommodate the etching process for forming the sidewall spacers, thereby avoiding the problem of insufficient protection of the DTC 12 during wet cleaning of the oxide layer and the etching process for forming the sidewall spacers. In contrast, the conventional HARP layer is lower than BOX layer and thus has limited edge portions. Consequently, damage tends to be caused to the DTC or BOX layer during the etching process for forming the sidewall spacers, which may lead to excessive exposure of the fin portion.

Optionally, after the sidewall spacers 29 are formed, the method may further include implanting ions to the fin structure 16 on opposite sides of the layer-stacked structures, forming source and drain regions of transistors in a surface portion of the fin structure 16.

After the source and drain regions are formed, the method may further include performing an EPI process to form source and drain EPI structures in the surface portion of the fin structure 16 on opposite sides of the layer-stacked structures.

In summary, according to the present invention, the HARP layer is first thinned by successive CMP and BHF processes and then completely removed from the fin structure region by using a mask layer. This can ensure absence of residues on the fin structure while preventing dishing of the HARP layer in the DT region, resulting in increased patterning efficiency, a reduced short risk and easier BHF etching control.

Further, according to the present invention, since the HARP layer is not dished at all, and has an adjustable thickness and width over the BOX layer, there are sufficiently large edge portions capable of accommodating the etching process for forming the sidewall spacers, thus avoiding the problems of insufficient protection of the DTC and excessive exposure of the fin portion during wet cleaning and etching and eventually resulting in a reduced EPI short risk.

Furthermore, compared with the prior art, the method of the present invention involves only one photolithography process and dispenses with the need for nitride removal and deposition, entailing a cyclic process, which is simpler, involves fewer steps, is more time-saving and can result in cost savings.

The present invention also provides a semiconductor structure fabricated according to the method as defined above, which comprises:
a semiconductor substrate, comprising: a BOX layer 11; a fin structure 16 located on a portion of the BOX layer 11; a DTC 12 extending through the BOX layer 11; an isolation layer located on each of the DTC 12 and the BOX layer 11 in a deep trench (DT) region; and an HARP layer 15 located on the isolation layer, the HARP layer 15 located above the BOX layer 11 in the DT region and a portion of the DTC 12 (more precisely, a trench portion 121 thereof), the semiconductor substrate divided into a fin structure region X and the DT region Y adjacent to and connected with the fin structure region X, the fin structure region X comprising the fin structure 16, the DT region Y comprising the DTC 12; a first oxide layer 25 located above the semiconductor substrate; layer-stacked structures located on the first oxide layer 25; and sidewall spacers 29 located on sidewalls of the layer-stacked structures. In this semiconductor structure of the present invention, the top of the HARP layer 15 is higher than a top of the BOX layer 11. The semiconductor structure is immune from the problem of dishing and associated with a reduced short risk. Moreover, the HARP layer 15 has sufficiently large edge portions capable of accommodating an etching process for forming the sidewall spacers, thereby preventing possible damage to the DTC 12 or to the BOX layer 11.

It is understood that, while the present invention has been described with reference to several preferred embodiments, the forgoing embodiments are not intended to limit the invention. In light of the teachings hereinabove, any person familiar with the art may make various possible variations and changes to the disclosed embodiments or modify them into equivalent alternatives, without departing from the scope thereof. Accordingly, any and all such simple variations, equivalent alternatives and modifications made to the foregoing embodiments without departing from the scope of the invention are intended to fall within the scope thereof.

It is further understood that the present invention is not limited to the particular methodology, compounds, materials, fabrication techniques, uses and applications described herein, as these may vary. It is also understood that the terminology used herein is for the purpose of describing particular embodiments only, and is not intended to limit the scope of the present invention. It must be noted that as used herein and in the appended claims, the singular forms “a” and “an” include the plural reference unless the context clearly dictates otherwise. Thus, for example, a reference to “a step” is a reference to one or more steps and may include sub-steps. All conjunctions used are to be understood in the most inclusive sense possible. Thus, the term “or” should be understood as having the definition of a logical “or” rather than that of a logical “exclusive or” unless the context clearly necessitates otherwise. Structures described herein are understood also to refer to functional equivalents of such structures. Language that may be construed to express approximation should be so understood unless the context clearly dictates otherwise.

What is claimed is:

1. A method for fabricating a semiconductor structure, comprising:
providing a semiconductor substrate, wherein the semiconductor substrate comprises: a buried oxide (BOX) layer; at least one fin structure located on a portion of the BOX layer; a deep trench capacitor (DTC) extending through the BOX layer; an isolation layer located on the fin structure, the DTC and the BOX layer; and a high aspect ratio process (HARP) layer located on the isolation layer, wherein the semiconductor substrate is divided into a fin structure region and a deep trench (DT) region adjacent to and connected with the fin structure region, wherein the fin structure region comprises the fin structure, and wherein the DT region comprises the DTC;
thinning the HARP layer, with a remaining portion of the HARP layer being retained above the BOX layer;
removing the isolation layer and the HARP layer from the fin structure region;
forming a first oxide layer over the semiconductor substrate;
forming layer-stacked structures on the first oxide layer; and
forming a sidewall spacer on each sidewall of the layer-stacked structure.

2. The method of claim 1, wherein thinning the HARP layer comprises:
performing a chemical mechanical polishing (CMP) process on the HARP layer, wherein the CMP process stops at the isolation layer; and
performing a wet etching process on the HARP layer resulting from the CMP process, wherein the wet etching process stops upon the remaining portion of the HARP layer reaching a predetermined thickness.

3. The method of claim 2, wherein the remaining portion of the HARP layer located above the BOX layer has a thickness in a range of 5 nm to 10 nm.

4. The method of claim 1, wherein the isolation layer comprises an oxide pad layer and a nitride pad layer, which are sequentially stacked one above the other, wherein removing the isolation layer and the HARP layer from the fin structure region comprises:
forming a second oxide layer over the semiconductor substrate which has undergone the thinning of the HARP layer;
forming a mask layer on the second oxide layer over the DT region;
with the mask layer serving as a mask, successively etching the second oxide layer and the HARP layer, thereby exposing the nitride pad layer;
with a remaining portion of the second oxide layer serving as a mask, etching the nitride pad layer, thereby exposing the oxide pad layer; and
removing an exposed portion of oxide pad layer and the remaining portion of the second oxide layer by performing a wet etching process.

5. The method of claim 4, wherein the mask layer comprises a patterned organic planarization layer (OPL) and a patterned anti-reflective coating (ARC), which are sequentially stacked one above the other.

6. The method of claim 5, wherein the formation of the mask layer comprises:
successively forming the OPL, the ARC and a photoresist layer over the second oxide layer;
forming a patterned photoresist layer by performing a photolithography process thereon, wherein the patterned photoresist layer covers the ARC located above the DT region; and
with the patterned photoresist layer serving as a mask, successively etching the OPL and the ARC to form a patterned OPL and a patterned ARC.

7. The method of claim 6, wherein removing the isolation layer and the HARP layer from the fin structure region further comprises, before etching the nitride pad layer with the remaining portion of the second oxide layer serving as a mask, removing the patterned OPL and ARC.

8. The method of claim 1, wherein at least one of the layer-stacked structures intersects the fin structure, and at least one of the layer-stacked structures is located on the first oxide layer above the DTC.

9. The method of claim 8, further comprising, after forming the sidewall spacer on each sidewall of the layer-stacked structure, forming a source EPI structure and a drain EPI structure in a surface portion of the fin structure on opposite sides of the layer-stacked structure.

10. A semiconductor structure, comprising:
a semiconductor substrate, comprising: a buried oxide (BOX) layer; a fin structure located on a portion of the BOX layer; a deep trench capacitor (DTC) extending through the BOX layer; an isolation layer covering each of the DTC and the BOX layer in a deep trench (DT) region; and a high aspect ratio process (HARP) layer located on the isolation layer, wherein the HARP layer is located above the BOX layer in the DT region and a portion of the DTC, wherein the semiconductor substrate is divided into the DT region and a fin structure region adjacent to and connected with the DT region, wherein the fin structure region comprises the fin structure, and wherein the DT region comprises the DTC;
a first oxide layer that is located above the semiconductor substrate;
layer-stacked structures that are located on the first oxide layer; and
a plurality of sidewall spacers that are located on sidewalls of the layer-stacked structures.

11. The semiconductor structure of claim 10, wherein the HARP layer located above the BOX layer has a thickness in a range of 5 nm to 10 nm.

12. The semiconductor structure of claim 10, wherein the isolation layer comprises an oxide pad layer and a nitride pad layer, which are sequentially stacked one above the other.

13. The semiconductor structure of claim 10, wherein at least one of the layer-stacked structures intersects the fin structure, and at least one of the layer-stacked structures is located on the first oxide layer above the DTC.
